(19) United States
(12) Patent Application Publication
(10) Pub. No.: US 2025/0259848 A1
(43) Pub. Date: Aug. 14, 2025

(54) DIVIDING METHOD OF WAFER

(71) Applicant: DISCO CORPORATION, Tokyo (JP)

(72) Inventors: Ishueh CHIANG, Tokyo (JP); Lars HUANG, Tokyo (JP); Isaic TSAI, Tokyo (JP); Hailey LIN, Tokyo (JP)

(21) Appl. No.: 19/041,343

(22) Filed: Jan. 30, 2025

(30) Foreign Application Priority Data
Feb. 8, 2024 (JP) 2024-018165

(51) Int. Cl. H01L 21/304; H01L 21/67; H01L 21/683; H01L 21/78

(52) U.S. Cl. CPC H01L 21/3043; H01L 21/6715; H01L 21/6838; H01L 21/78

(57) ABSTRACT

A dividing method of a wafer includes cutting a front surface of the wafer to a predetermined depth with a cutting blade to form bottomed cut-grooves, applying a water-soluble liquid resin to the front surface of the wafer and drying the water-soluble liquid resin to fill the cut-grooves with the resulting dried water-soluble resin, grinding the wafer at the back surface thereof with grinding stones, so that the cut-grooves are allowed to appear in the back surface of the wafer and the wafer is divided into individual chips, and ejecting rinse water against the wafer, which has been divided into the chips, to remove the water-soluble resin.

### BACKGROUND OF THE INVENTION

### Field of the Invention

The present invention relates to a dividing method of a wafer, which divides the wafer along a plurality of intersecting streets.

### Description of the Related Art

In a fabrication process of semiconductor devices, for example, a disk-shaped semiconductor wafer (hereinafter simply called a “wafer”) is defined at a front surface thereof into a plurality of device regions along streets (scribe lines) formed in a lattice pattern, and devices such as integrated circuits (ICs) or large-scale integration (LSI) circuits are formed in the individual device regions, respectively. A plurality of device chips is obtained by dividing, along the streets, the wafer on which such many devices are formed. The chips divided as described above are packaged and extensively used in various kinds of electronic equipment such as personal computers and smartphones.

In recent years, there is a demand for downsizing and weight reduction of various kinds of electronic equipment, so that chips used in these electronic equipment tend to have a smaller thickness. Thinning of the chips is performed by grinding the wafer at a back surface therefore before the wafer is divided. If the thinned wafer is divided into the individual chips by dicing or the like, however, a problem arises in that chipping or the like is prone to occur on the chips.

As a wafer dividing method that resolves the above-described problem, a dividing technique called “Dicing Before Grinding” was developed, and has already found practical utility (see, for example, JP S64-038209 A). This dicing before grinding is a method that divides a wafer into individual chips by forming cut-grooves to a predetermined depth (a depth to such an extent as not to completely cut apart the wafer) from a front surface of the wafer before grinding the wafer at a back surface thereof, and with a protective sheet bonded on the front surface of the wafer, grinding the wafer at the back surface thereof to allow the cut-grooves to appear.

In the method that the wafer is divided into the individual chips by the above-described dicing before griding, however, the grinding is continued until the chips have a desired thickness even after the cut-grooves have appeared in the back surface of the wafer. Accordingly, abrasive grits separated from grinding stones and grinding debris ground off from the wafer penetrate into the cut-grooves (gaps between the adjacent chips themselves), thereby raising a problem such as contamination of the chips at side surfaces thereof or induction of chipping, damage, or the like of the chips.

In JP 2001-176822A, filling of cut-grooves of a wafer with an interference prevention material such as a curable liquid resin is hence proposed. In JP 2009-224659A, a method is also proposed in which, after a solvent-free hydrophilic resin is applied in a liquid or viscoelastic form to a front surface of a wafer, where cut-grooves are formed, and is cured, the wafer is ground at a back surface thereof to divide the wafer into individual chips, and then the hydrophilic resin is brought into contact with warm water of 40° C. or higher to remove it from the individual chips.

### SUMMARY OF THE INVENTION

However, the wafer dividing methods proposed in JP 2001-176822A and JP 2009-224659A have a problem in that time is needed for the removal of the curable liquid resin or the hydrophilic resin and productivity is poor accordingly.

The present invention therefore has as an object thereof the provision of a method of dividing a wafer, which can improve the productivity by removing a resin, which covers cut-grooves of the wafer, in a short time.

In accordance with an aspect of the present invention, there is provided a method of dividing a wafer, which is defined at a front surface thereof into a plurality of regions by a plurality of intersecting streets and carries devices formed in the regions, respectively, along the streets to obtain a plurality of chips. The method includes holding the wafer on a first chuck table of a cutting machine with the front surface directed upward, cutting the front surface of the wafer to a predetermined depth along the streets with a cutting blade of the cutting machine to form bottomed cut-grooves, applying a water-soluble liquid resin from a side of the front surface of the wafer and drying the water-soluble liquid resin to fill the cut-grooves with the resulting dried water-soluble resin, bonding a protective sheet onto the front surface of the wafer, holding the wafer on a second chuck table of a grinding machine with a back surface thereof directed upward, grinding the wafer, which is held on the second chuck table, at the back surface thereof with grinding stones, so that the cut-grooves are allowed to appear in the back surface of the wafer and the wafer is divided into individual chips, and ejecting rinse water against the wafer, which has been divided into the chips, to remove the water-soluble resin filled in the cut-grooves.

According to the wafer dividing method of the present invention, a relatively small amount of a water-soluble resin layer filled in each cut-groove can be dissolved and removed in a short time. As a result, the productivity of the chips can be improved. In addition, as the cut-grooves are filled with the water-soluble resin layers in the cutting, sticking of cutting debris to side surfaces of the divided chips can be avoided.

The above and other objects, features and advantages of the present invention and the manner of realizing them will become more apparent, and the invention itself will best be understood from a study of the following description and appended claim with reference to the attached drawings depicting or illustrating a preferred embodiment of the invention.

### BRIEF DESCRIPTION OF THE DRAWINGS

FIG. 1 is a perspective view of a wafer;

FIG. 2 is a flow chart illustrating procedures of a wafer dividing method according to the present invention;

FIG. 3 is a side cross-sectional view depicting a first holding step in the wafer dividing method according to the present invention;

FIG. 4 is a side cross-sectional view depicting a cut-groove forming step in the wafer dividing method according to the present invention;

FIG. 5 is a side cross-sectional view depicting a cut-groove rinsing step in the wafer dividing method according to the present invention;

FIG. 6 is a side cross-sectional view depicting a water-soluble resin filling step in the wafer dividing method according to the present invention;

FIG. 7 is a side cross-sectional view depicting a protective sheet bonding step in the wafer dividing method according to the present invention;

FIG. 8 is a side cross-sectional view depicting a second holding step in the wafer dividing method according to the present invention;

FIG. 9 is a side cross-sectional view depicting a grinding step in the wafer dividing method according to the present invention; and

FIG. 10 is a side cross-sectional view depicting a water-soluble resin removing step in the wafer dividing method according to the present invention.

### DETAILED DESCRIPTION OF THE PREFERRED EMBODIMENT

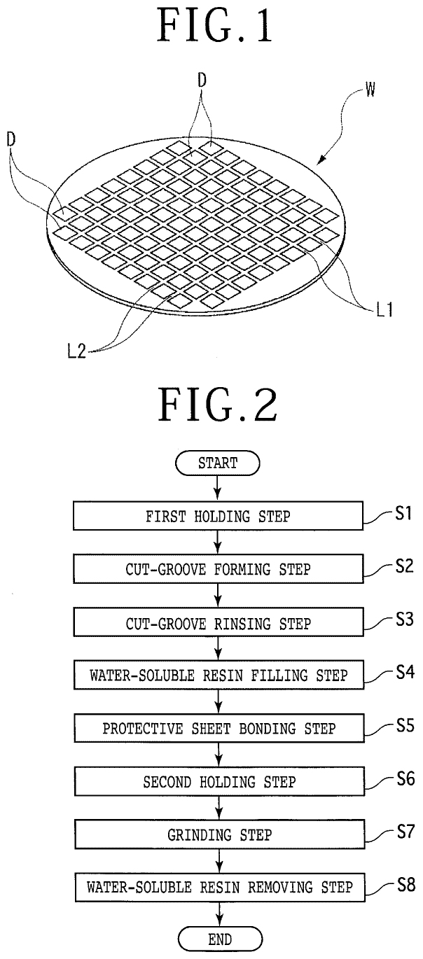

With reference to the attached drawings, a description will be made about an embodiment of the present invention. As depicted in FIG. 1, a wafer W that is to be divided by a dividing method according to the present invention is, for example, a thin disk-shaped member formed of single crystal silicon (Si), its front surface (an upper surface in FIG. 1) is defined into a plurality of rectangular regions by intersecting streets (scribe lines) L1 and L2 arrayed in a lattice pattern, and devices D such as ICs or LSIs are formed in the individual rectangular regions, respectively. It is to be noted that, as the material of the wafer W, silicon carbide (Sic), glass, ceramics, sapphire, or the like may be used besides silicon (Si).

The wafer dividing method according to the present invention will hereinafter be described with reference to FIGS. 2 to 11.

The dividing method according to the present invention for the wafer W is a method, in which the wafer W (see FIG. 1) is divided into a plurality of chips C (see FIG. 11) by sequentially performing 1) a first holding step (step S1), 2) a cut-groove forming step (step S2), 3) a cut-groove rinsing step (step S3), 4) a water-soluble resin filling step (step S4), 5) a protective sheet bonding step (step S5), 6) a second holding step (step 6), 7) a grinding step (step S7), and 8) a water-soluble resin removing step (step S8), in this order as depicted in FIG. 2. These individual steps will hereinafter be described respectively.

### 1) First Holding Step:

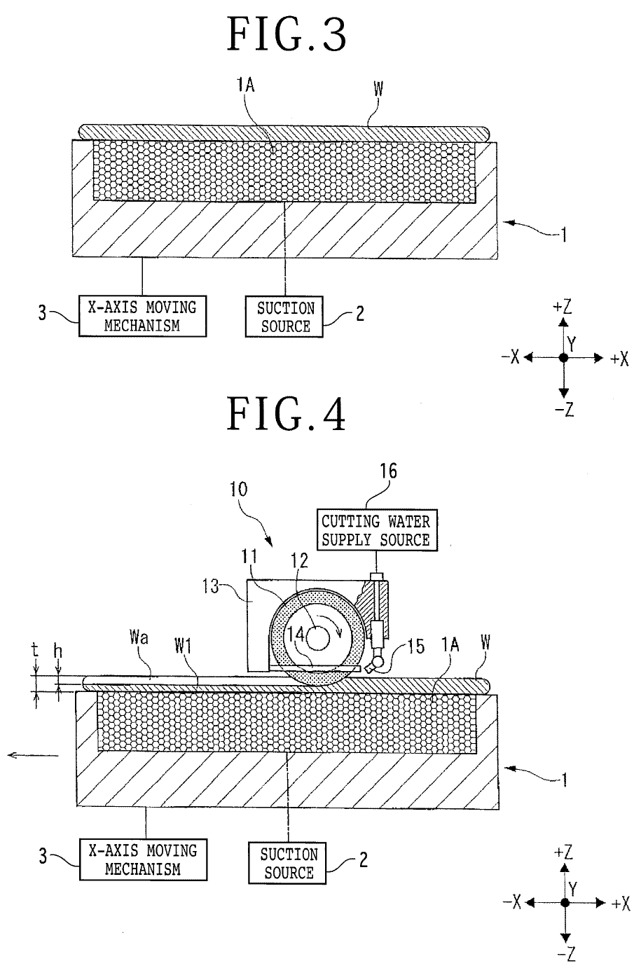

The first holding step is to hold the wafer W on a holding surface of a disk-shaped first chuck table 1 of a cutting machine as depicted in FIG. 3. It is to be noted that, in FIGS. 3 and 4, a left-right direction is assumed to be an X-axis direction, a direction perpendicular to the drawing sheet is assumed to be a Y-axis direction, and an up-down direction is assumed to be a Z-axis direction.

Here, a disk-shaped porous member 1A of a porous material is centrally fitted in an upper portion of the first chuck table 1, and an upper surface of this porous member 1A constitutes a holding surface on which the wafer W is held. The porous member 1A is connected to a suction source 2 such as a vacuum pump or an ejector, and on the holding surface as the upper surface of the porous member 1A, the wafer W is placed with the front surface (the surface on which the devices D (see FIG. 1) are formed) directed upward. As the porous member 1A is then evacuated by the suction source 2, a negative pressure occurs in the porous member 1A, so that the wafer W is drawn by the negative pressure and is held under suction on the holding surface of the porous member 1A.

Further, the first chuck table 1 is horizontally movable in the X-axis direction (a cutting feed direction) by an X-axis moving mechanism 3, and is also horizontally movable in the Y-axis direction (an indexing direction) by an undepicted Y-axis moving mechanism. It is to be noted that the X-axis moving mechanism 3 and the undepicted Y-axis moving mechanism are each constituted by a known ball screw mechanism or the like.

### 2) Cut-Groove Forming Step:

The cut-groove forming step is to form lattice-patterned, bottomed cut-grooves Wa by cutting (half-cutting) the front surface of the wafer W, which has been held on the first chuck table 1 of the cutting machine in the first holding step, to a predetermined depth h with a cutting blade 11 disposed on a cutting unit 10 depicted in FIG. 4. In this cut-groove forming step, the depth h of the lattice-patterned, bottomed cut-grooves Wa to be formed in the front surface of the wafer W is set to a value that is a depth to such an extent as not to completely cut apart the wafer W and is smaller than a thickness t of the wafer W (h<t). In the wafer W after the cut-grooves Wa have been formed, uncut portions W1 of a thickness (t−h) therefore remain, and by these uncut portions W1, the wafer W retains its initial disk shape.

Here, the cutting blade 11 is a thin, disk-shaped cutting tool, and is attached to a tip of a rotatable spindle 12 arranged along the Y-axis, and the spindle 12 is rotated at a high speed along with the cutting blade 11 by an undepicted spindle motor built in a housing 13 of the cutting unit 10. Further, the cutting unit 10 is supported movably in the Z-axis direction (cut-in direction) by an undepicted Z-axis moving mechanism. It is to be noted that the housing 13 is provided with both ejection nozzles 14 and 15 which eject cutting water toward the cutting blade 11 during cutting processing, and these ejection nozzles 14 and 15 are both connected to a cutting water supply source 16. It is to be noted that pure water is suitably used as the cutting water.

In the front surface of the wafer W, the cut-grooves Wa of the predetermined depth h are therefore formed along the streets L1, for example, in one direction (see FIG. 1) by the cutting (half-cutting) with the cutting blade 11 that is rotating at the high speed. Described specifically, when the first chuck table 1 is moved along with the wafer W in the X-axis direction (an arrow direction in FIG. 4) by the X-axis moving mechanism 3 and is positioned below the cutting unit 10, the front surface of the wafer W is imaged by an undepicted imaging unit arranged in the cutting unit 10. When an image is captured by the imaging of the front surface of the wafer W with the imaging unit, the street L1 to be cut is detected by pattern matching processing based on the image.

When the street L1 of the wafer W is detected as mentioned above, the position in the Y-axis direction of the cutting blade 11 of the cutting unit 10 is indexed by the undepicted Y-axis moving mechanism, and the position in the Y-axis direction of the cutting blade 11 is brought into alignment with the street L1 to be cut.

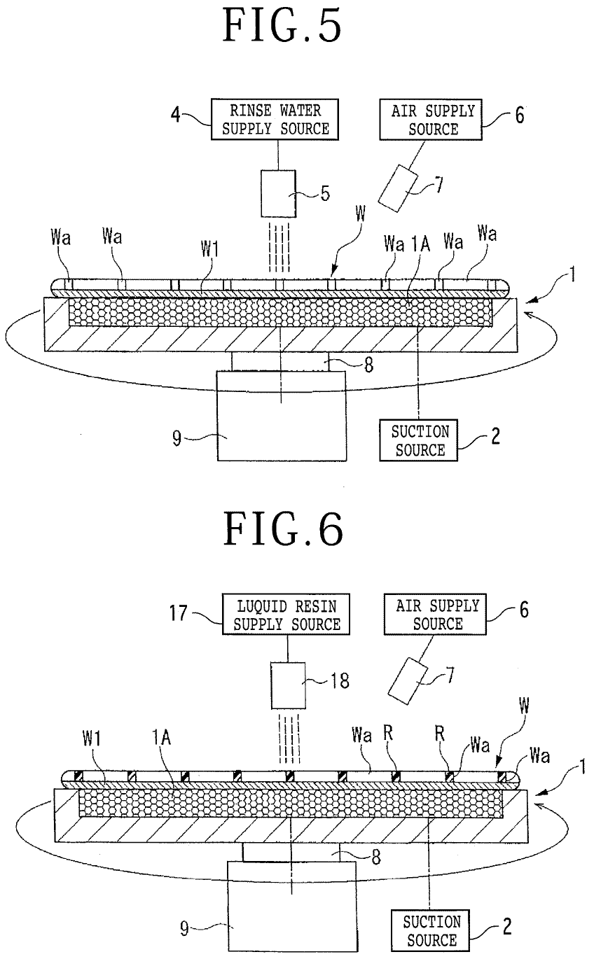

With the cutting blade 11 rotationally driven at the high speed, the cutting blade 11 is then lowered from the above-described state by a predetermined cut amount with the Z-axis moving mechanism, and, at the same time, the first chuck table 1 and the wafer W held thereon are moved in the X-axis direction by the X-axis moving mechanism 3. The wafer W is therefore cut along the street L1 by the cutting blade 11. After such an operation has been performed to all the streets L1 in the one direction, the first chuck table 1 and the wafer W held thereon are rotated by 90° with a rotating mechanism (a motor 9 depicted in FIGS. 5 and 6), and on the wafer W, cutting along the street L2 (see FIG. 1) in the other direction orthogonal to the streets L1, the cutting of which has been completed, is similarly performed. As a result, the cut-grooves Wa of the predetermined depth h along the streets L1 and L2 are formed in the lattice pattern in the front surface of the wafer W.

### 3) Cut-Groove Rinsing Step:

The cut-groove rinsing step is to rinse the cut-grooves Wa of the predetermined depth h, which have been formed in the lattice pattern in the front surface of the wafer W in the cut-groove forming step as a preceding step, with rinse water as depicted in FIG. 5. Here, above the first chuck table 1, an ejection nozzle 5 connected to a rinse water supply source 4 and an ejection nozzle 7 connected to an air supply source 6 are arranged. Further, the motor 9 is connected as a rotary drive source to a rotating shaft 8 extending vertically downward from a center of the first chuck table 1. It is to be noted that pure water is suitably used as the rinse water.

Accordingly, in this cut-groove rinsing step, the first chuck table 1 and the wafer W held thereon are rotationally driven at a predetermined speed in the indicated arrow direction about a central axis of the rotating shaft 8 by the motor 9, and, at the same time, the rinse water supplied from the rinse water supply source 4 is ejected from the ejection nozzle 5 toward the lattice-patterned, bottomed cut-grooves Wa formed in the front surface of the wafer W, so that each cut groove Wa is rinsed with the rinse water. By this rinsing of the cut-grooves Wa with the rinse water, cutting debris occurred during the cutting processing of the wafer W and stuck in the cut grooves Wa is removed. Owing to the ejection of the air, which is supplied from the air supply source 6, from the ejection nozzle 7 toward the front surface of the wafer W, the cutting debris removed from the cut-grooves Wa and the rinse water are then blown away and removed.

### 4) Water-Soluble Resin Filling Step:

The water-soluble resin filling step is to fill each cut-groove Wa of the wafer W with a water-soluble resin layer R as depicted in FIG. 6 by applying a water-soluble liquid resin r to the front surface of the wafer W and drying it. It is to be noted that polyvinyl alcohol (PVA), polyvinylpyrrolidone (PVP), or the like is used as the water-soluble liquid resin r.

Accordingly, in the water-soluble resin filling step, the first chuck table 1 and the wafer W held thereon are rotationally driven at a predetermined speed in the indicated arrow direction about the central axis of the rotating shaft 8 by the motor 9, and, at the same time, the water-soluble liquid resin r supplied from a liquid resin supply source 17 to a nozzle 18 is dropped from the nozzle 18 toward a central portion of the upper surface of the wafer W. The water-soluble liquid resin r dropped to the central portion of the upper surface of the wafer W is then caused to spread outward in a radial direction of the wafer W by a centrifugal force, so that the lattice-patterned, bottomed cut-grooves Wa formed in the front surface of the wafer W are filled with the water-soluble resin layers R. Further, high-speed rotation of the first chuck table 1 at 2,000 rpm allows the water-soluble liquid resin r to dry so that the water-soluble resin layers R are formed. Air may be ejected from the ejection nozzle 7 toward the central portion of the upper surface of the wafer W in order to accelerate the drying of the water-soluble liquid resin r. The water-soluble resin filling step may also be performed by holding the wafer W on a table different from the cutting machine instead of the first chuck table 1. It is to be noted that the water-soluble liquid resin r may be filled in the cut-grooves Wa by horizontally moving the nozzle 18 and the wafer W relative to each other.

### 5) Protective Sheet Bonding Step:

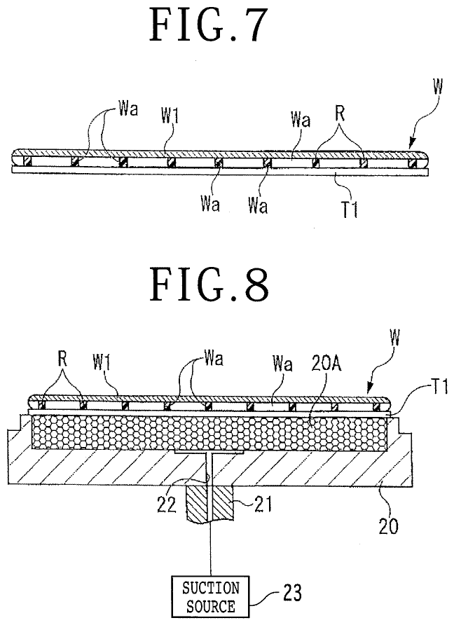

The protective sheet bonding step is to form a workset WS1, which is depicted in FIG. 7, by bonding a sheet T1 onto the side of the front surface of the wafer W in the cut-grooves Wa of which the water-soluble resin layers R have been filled in the water-soluble resin filling step as a preceding step.

The sheet T1 is therefore bonded on the entirety of the front surface (a lower surface in FIG. 7) of the wafer W as depicted in FIG. 7, so that the workset WS1 is formed. It is to be noted that the sheet T1 is a self-adhesive sheet provided on a base material thereof with a self-adhesive layer, or a thermal fusion-bonding sheet.

The workset WS1 depicted in FIG. 7 and formed as described above will be described regarding cases where it is subjected to the second holding step, grinding step, and water-soluble resin removing step to be mentioned as succeeding steps.

### 6) Second Holding Step:

The second holding step is to hold the workset WS1, which is depicted in FIG. 7, on a second chuck table 20 of a grinding machine as depicted in FIG. 8. Here, the second chuck table 20 of the grinding machine is a disk-shaped member, and a disk-shaped porous member 20A of a porous material is fitted in a central upper portion of the second chuck table 20. Further, an upper surface of the porous member 20A constitutes a holding surface, and the porous member 20A is selectively connected to a suction source 23 such as a vacuum pump or an ejector via a communication channel 22 formed centrally through the second chuck table 20 and a rotating shaft 21.

Accordingly, in this second holding step, the workset WS1 is placed on the second chuck table 20, and the wafer W is held under suction on the holding surface of the porous member 20A of the second chuck table 20 with the back surface thereof directed upward. Described specifically, when the porous member 20A is evacuated by the suction source 23 with the wafer W placed on the holding surface of the porous member 20A of the second chuck table 20 via the sheet T1, a negative pressure occurs in the porous member 20A, so that the wafer W of the workset W1 is drawn by the negative pressure and is held under suction on the holding surface of the porous member 20A via the sheet T1.

### 7) Grinding Step:

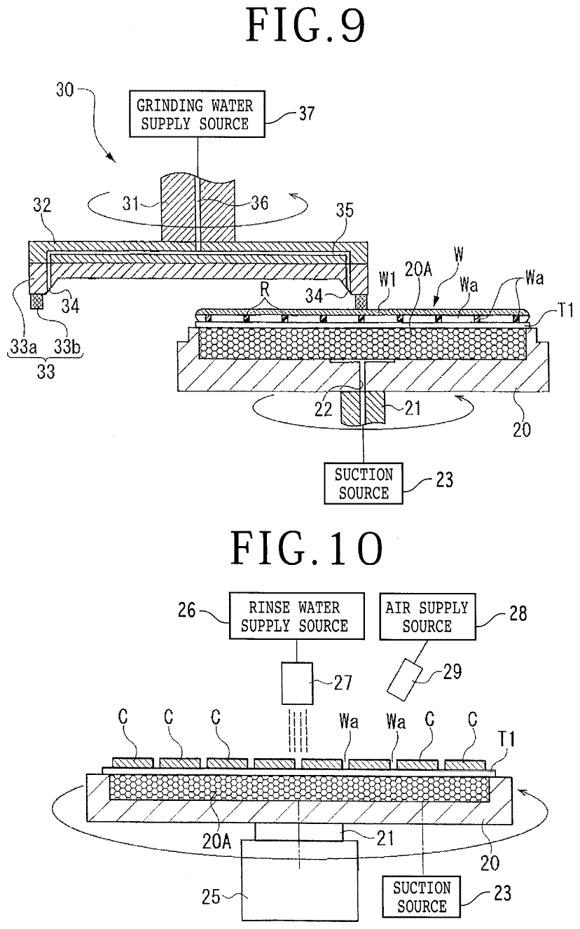

The grinding step is, as depicted in FIG. 9, to allow the cut-grooves Wa to appear in the back surface of the wafer W by grinding, with a plurality of block-shaped grinding stones 33b of the grinding machine, the back surface (an upper surface in FIG. 9) of the wafer W of the workset WS1 which has been held on the second chuck table 20 of the grinding machine in the second holding step as a preceding step.

Described specifically, as depicted in FIG. 9, a grinding unit 30 is arranged above the second chuck table 20, and a grinding wheel 33 is detachably secured to a lower surface of a disk-shaped mount 32 that is connected to a lower end of a rotatable vertical spindle 31 of the grinding unit 30. Here, the grinding wheel 33 is constituted by a disk-shaped base 33a, and the grinding stones 33b arranged in an annular pattern and secured to a lower surface of the base 33a.

Further, the spindle 31 of the grinding unit 30 and the grinding wheel 33 secured to the lower end of the spindle 31 are rotationally driven at a predetermined speed in an arrow direction by an undepicted spindle motor, and is moved up or down by an undepicted Z-axis moving mechanism (lift mechanism) at the same time. Furthermore, a plurality of ejection nozzles 34 is vertically formed in the base 33a of the grinding wheel 33 on an inner side in a radial direction of the grinding stones 33b, and these ejection nozzles 34 are connected to a grinding water supply source 37 via a plurality of communication paths 35 formed in the mount 32 and a communication channel 36 formed through an axial center of the spindle 31. It is to be noted that, as depicted in FIG. 10, a motor 25 as a rotary drive source is connected to the rotating shaft 21 extending vertically downward from the second chuck table 20.

When the second chuck table 20 and the workset WS1 held thereon are rotationally driven at a predetermined speed in an arrow direction of FIG. 9 by the motor 25 depicted in FIG. 10, and, at the same time, the grinding wheel 33 is moved down by a predetermined amount (a grinding margin) with the undepicted Z-axis moving mechanism (lift mechanism), the wafer W is hence evenly ground at the back surface thereof (the upper surface in FIG. 9) by the rotating grinding stones 33b. Here, the grinding margin for the back surface of the wafer W is set to a value that the lattice-patterned, bottomed cut grooves Wa formed in the wafer W are allowed to appear in the back surface of the wafer W, specially to a value that a remaining portion (a portion applied with hatching in FIG. 9, in other word, the uncut portion depicted in FIG. 4) W1 other than the cut-grooves Wa of the wafer W is removed in its entirety by the grinding and the thickness of the wafer W after the grinding has a value equal to or smaller than the depth h (see FIG. 4) of the cut-grooves Wa.

Further, while the wafer W is being ground at the back surface thereof in this grinding step, grinding water from the grinding water supply source 37 is supplied from the ejection nozzles 34 to contact areas (grinding areas) between the grinding stones 33b and the wafer W via the communication channel 36 and the communication paths 35, so that the contact areas (grinding areas) between the grinding stones 33b and the wafer W are cooled to suppress a rise in temperature, and, at the same time, grinding debris occurred by the grinding is washed away. It is to be noted that pure water is suitably used as the grinding water.

As a result of the grinding of the back surface of the wafer W in this grinding step, the lattice-patterned, bottomed cut-grooves Wa are therefore allowed to appear in the back surface (the upper surface in FIG. 10) of the wafer W, whereby the wafer W is divided into the chips C as depicted in FIG. 10.

### 8) Water-Soluble Resin Removing Step:

The water-soluble resin removing step is to remove the water-soluble resin layers R (see FIG. 9) remaining in the lattice-patterned, bottomed cut-groove Wa of the wafer W in the back surface of which the cut-grooves Wa have been allowed to appear by the grinding in the grinding step as a preceding step. Described specifically with reference to FIG. 10, in this water-soluble resin removing step, rinse water that is supplied from a rinse water supply source 26 arranged above the second chuck table 20 is ejected toward the central portion of the upper surface of the wafer W from an ejection nozzle 27 while the second chuck table 20 and the workset WS1 held thereon are rotated at a predetermined speed in the indicated arrow direction about an axial center of the shaft 21 by the motor 25.

The rinse water ejected from the ejection nozzle 27 to the central portion of the upper surface of the wafer W is then caused to evenly spread toward an outer peripheral portion of the wafer W by a centrifugal force, so that the water-soluble resin layers R (see FIG. 9) remaining in the cut-grooves Wa of the wafer W are dissolved and removed with the rinse water. The wafer W of which the water-soluble resin layers R have been removed from the cut-grooves Wa is then dried by ejection of air, which is supplied from an air supply source 28 arranged above the second chuck table 20, from an ejection nozzle 29 to the upper surface (back surface) of the wafer W. It is to be noted that pure water is suitably used as the rinse water. It is also to be noted that the water-soluble resin layers R may be dissolved and removed or dried by moving the ejection nozzles 27 and 29 and the wafer W relative to each other along the cut-grooves Wa.

As described above, the water-soluble resin layers R remaining in the cut-grooves Wa of the wafer W is dissolved and removed with the rinse water in the water-soluble resin removing step, whereby the wafer W is isolated into the chips C as depicted in FIG. 10.

According to the dividing method of the present embodiment for the wafer W, it is configured to divide the wafer W into the chips C by forming, in the water-soluble resin filling step, the water-soluble resin layers R in the lattice-patterned, bottomed cut-grooves (half cut-grooves) Wa which have been formed in the front surface (the surface on which the devices D are formed) of the wafer W in the cut-groove forming step, grinding the wafer W at the back surface thereof and allowing the cut-grooves Wa to appear in the grinding step, and in the water-soluble resin removing step, dissolving and removing, with the rinse water, the water-soluble resin layers R filled in the appeared cut-grooves Wa, as described above. A relatively small amount of the water-soluble resin layer R filled in each cut-groove Wa can hence be dissolved and removed in a short time. As a result, the productivity of the chips C can be improved. In addition, as the cut-grooves Wa are filled with the water-soluble resin layers R in the cutting step, sticking of cutting debris to side surfaces of the divided chips C can be avoided.

Further, sticking of cutting debris to the cut-grooves Wa can also be avoided because the cut-grooves Wa formed in the wafer W in the cut-groove forming step are configured to be rinsed in the cut-groove rinsing step in the present embodiment.

Furthermore, sticking of abrasive grits or cutting debris to the side surfaces of the divided chips C can also be avoided in the present embodiment because a dried layer of the water-soluble liquid resin r as formed on the front surface of the wafer W in the water-soluble resin filling step is configured to be dissolved and removed with the rinse water in the water-soluble resin removing step.

The present invention is not limited to the details of the above-described preferred embodiment. The scope of the invention is defined by the appended claims and all changes and modifications as fall within the equivalence of the scope of the claims are therefore to be embraced by the invention.

What is claimed is:

1. A method of dividing a wafer, which is defined at a front surface thereof into a plurality of regions by a plurality of intersecting streets and carries devices formed in the regions, respectively, along the streets to obtain a plurality of chips, the method comprising:
holding the wafer on a first chuck table of a cutting machine with the front surface directed upward,
cutting the front surface of the wafer to a predetermined depth along the streets with a cutting blade of the cutting machine to form bottomed cut-grooves,
applying a water-soluble liquid resin from a side of the front surface of the wafer and drying the water-soluble liquid resin to fill the cut-grooves with the resulting dried water-soluble resin,
bonding a protective sheet onto the front surface of the wafer,
holding the wafer on a second chuck table of a grinding machine with a back surface thereof directed upward,
grinding the wafer, which is held on the second chuck table, at the back surface thereof with grinding stones, so that the cut-grooves are allowed to appear in the back surface of the wafer and the wafer is divided into individual chips, and
ejecting rinse water against the wafer, which has been divided into the chips, to remove the water-soluble resin filled in the cut-grooves.
